(19) United States
(12) Patent Application Publication
(10) Pub. No.: US 2017/0275083 A1
(43) Pub. Date: Sep. 28, 2017

(54) Substrate Cassette

(71) Applicants: BOE Technology Group Co., Ltd., Beijing (CN); Hefei BOE Optoelectronics Technology Co., Ltd., Hefei (CN)

(72) Inventor: Xiaobao Li, Beijing (CN)

(73) Assignees: BOE Technology Group Co., Ltd., Beijing (CN); Hefei BOE Optoelectronics Technology Co., Ltd., Hefei (CN)

(21) Appl. No.: 15/509,457

(22) PCT Filed: Apr. 21, 2016
(86) PCT No.: PCT/CN2016/079889

§ 371 Date: Mar. 7, 2017

(30) Foreign Application Priority Data
Sep. 10, 2015 (CN) 201520704730.X

(51) Int. Cl. B65D 85/48; H01L 21/673

(52) U.S. Cl. CPC B65D 85/48; H01L 21/6732

(57) ABSTRACT

A substrate cassette can solve a problem in prior art that the substrates having been placed inside the substrate cassette may be crashed or broken when the substrate cassette is conveyed or is picked up and placed down by a mechanical arm which is not under control of a computer system. The substrate cassette defines multiple bearing layers configured to bear substrates thereon, a sensing element is provided in each of the bearing layers, and a warning element is provided outside the substrate cassette to correspond to the sensing element. The sensing element is configured to sense whether a substrate is placed on the bearing layer; and the warning element is configured to send a warning signal when sensing the substrate on the bearing layer by the sensing element.

### TECHNICAL FIELD

At least one embodiment of the present disclosure relates to a substrate cassette.

### BACKGROUND

A thin film transistor liquid crystal display (TFT-LCD) has occupied a leading position of current display filed for its advantages such as small volume, low power consumption, no radiation and high resolution, and is widely applied in a variety of digital information devices.

A known TFT-LCD generally includes a backlight module and a liquid crystal panel. The liquid crystal panel comprises an array substrate, a color film substrate and a liquid crystal layer disposed between the array substrate and the color film substrate. In a manufacturing process of a liquid crystal display, the substrates are required to be moved back and forth between relatively independent fabrication devices more than one time. In practical manufacturing, a substrate cassette capable of bearing a plurality of substrates is generally used as a bearing apparatus which stores and conveys substrates, and then the substrate cassette is placed on a mechanical conveying apparatus to be moved back and forth between respective fabrication devices.

In prior art, the substrate cassette generally includes a cassette house and a plurality of bearing layers provided inside the cassette house. The cassette house has an opening in only one side, and a mechanical arm can pick up and down the substrates through the opening. Every bearing layer includes a plurality of supporting plates provided on inner walls of the cassette house and configured to bear the substrates. The substrates are placed on the supporting plates.

The substrate cassette is designed to have a structure consisting of a plurality of layers. Under control of a computer system, the mechanical arm picks up the substrates from the substrate cassette, or put the substrates into the substrate cassette, or transfers the substrate cassette by a transport device. In practical application, temporary transactions are often processed in a manner of off-line operation (that is, the mechanical arm is manually controlled by an operator but not by the computer system). In the manner of off-line operation, since the operator, the mechanical arm and the transport device can not perceive whether a substrate exist in the substrate cassette or the number of the substrates, the substrates having been placed inside the substrate cassette may be crashed or broken when the substrate cassette is conveyed or picked up and put down.

### SUMMARY

At least one embodiment of the present disclosure provides a substrate cassette, to solve a problem in prior art that the substrates having been placed inside the substrate cassette may be crashed or broken when the substrate cassette is conveyed or picked up and put down by the mechanical arm which is not operated under control of a computer system.

At least one embodiment of the present disclosure provides a substrate cassette which defines multiple bearing layers therein, each of the bearing layers is configured to bear a substrate thereon, a sensing element is provided in each of the bearing layers, and a warning element is provided outside the substrate cassette to correspond to the sensing element; wherein the sensing element is configured to sense a substrate on the bearing layer, and the warning element is configured to send a warning signal when the substrate is sensed by the sensing element.

In one example, each of the bearing layers includes at least one side wall and at least one supporting plate fixed on the side wall.

In one example, the side wall of the bearing layer is defined by at least one inner wall of the substrate cassette.

In one example, the sensing element is provided in the at least one supporting plate of each of the bearing layers, and the sensing element is a pressure sensor or a photoelectric sensor.

In one example, the sensing element is provided on the at least one side wall of each of the bearing layers, and the sensing element is a photoelectric sensor.

In one example, the photoelectric sensor is a scattered reflection photoelectric sensor.

In one example, a groove is provided in a top surface of the supporting plate, and the sensing element is provided in the groove.

In one example, a groove is provided in the at least one side wall of each of the bearing layers, and the sensing element is provided in the groove.

In one example, the warning element is an indicator light or an infrared light-emitting device.

In one example, the substrate cassette further includes: a processor which is electrically connected with respective sensing elements and configured to process sensing signals from the respective sensing elements; and a display which is connected with the processor and configured to display processing results from the processor.

In one example, the substrate cassette further includes a wireless transceiver element which is electrically connected with the processor and configured to send warning information to a target receiver according to the processing results from the processor.

In one example, the substrate cassette further includes a power supply element which is connected with at least one of the processor, the display, the respective sensing elements, the respective wireless transceivers and the respective warning elements, to supply power thereto.

In one example, the substrate cassette further includes a charging element which is connected with the power supply element to charge the power supply element.

The substrate cassette provided by the embodiments of the disclosure can detect whether the bearing layer bears a substrate by the sensing element provided in the bearing layer, and can send a warning signal by the warning element when it's detected that the bearing layer bears the substrate, so that the operator or the conveying apparatus can take corresponding actions according to the warning signal sent from the warning element, to avoid the problem that the substrates having been placed inside the substrate cassette are crashed or broken etc., when the substrate cassette is unsuitably operated

### BRIEF DESCRIPTION OF THE DRAWINGS

The embodiments of the disclosure will be illustrated below in more details in connection with the drawings, in order to make those skilled in related arts understand the disclosure more clearly. In the drawings,

FIG. 1 is a schematic diagram illustrating a structure of a substrate cassette provided by one embodiment of the present disclosure;

FIG. 2 is a schematic diagram illustrating a cross-sectional structure of a first type of substrate cassette provided by an embodiment of the present disclosure;

FIG. 3 is a schematic diagram illustrating a cross-sectional structure of a second type of substrate cassette provided by an embodiment of the present disclosure;

FIG. 4 is a schematic diagram illustrating a cross-sectional structure of a third type of substrate cassette provided by an embodiment of the present disclosure;

FIG. 5 is a schematic frame diagram of the substrate cassette provided by the embodiment of the present disclosure.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

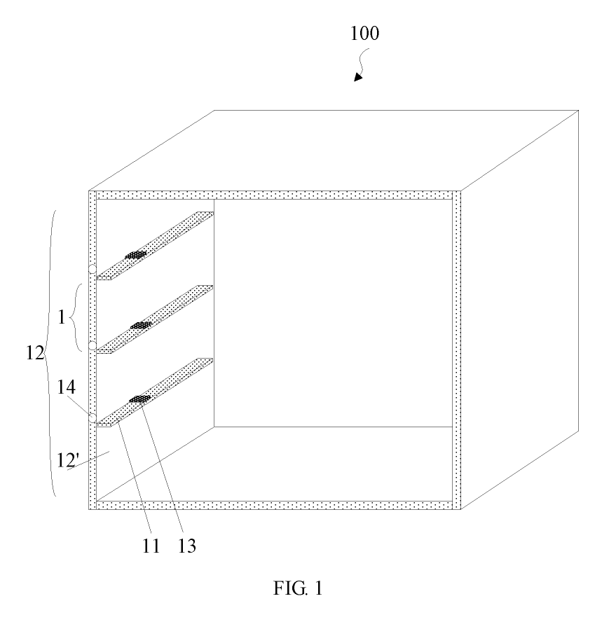

Referring to FIG. 1, an embodiment of the disclosure provides a substrate cassette 100, including a plurality of bearing layer 1 provided inside the substrate cassette and configured to bear substrates, a sensing element 13 is provided on each of the bearing layers 1, and a warning element 14 is provided outside the substrate cassette 100 to correspond to the sensing element 13. The sensing element 13 is configured to sense whether any substrate is placed on the bearing layer 1, and the warning element 14 is configured to send a warning signal when a substrate having been placed on the bearing layer 1 is sensed by the sensing element 13.

In this embodiment, whether the bearing layer 1 bears a substrate can be detected (determined) by the sensing element 13 provided in the bearing layer 1, and a warning signal will be sent by the warning element 14 provided corresponding to the sensing element 13 when it's determined that the bearing layer 1 bears the substrate, so that the operator or the conveying apparatus can take corresponding actions according to the warning signal sent from the warning element 14, so as to avoid the problem that the substrates having been placed inside the substrate cassette are crashed or broken when the substrate cassette is unsuitably operated.

In one example, the plurality of bearing layers 1 includes at least one side wall 12′ defined by an inner wall 12 of the substrate cassette 100, and at least one supporting plate 11 fixed on the side wall 12′. In other words, each of the bearing layers 1 includes at least one side wall 12′ and at least one supporting plate 11 fixed on the side wall 12′. For example, the bearing layer 1 can include a left and a right side walls 12′ and two supporting plates 11 fixed on the left and the ride side walls 12′ respectively. It should be noted that, each of the bearing layers 1 illustrated in FIG. 1 only includes a side wall 12′ and a supporting plate 11 on one side of the substrate cassette for purpose of simplification. It should be noted that, a material of the inner walls of the substrate cassette of the embodiment of the disclosure is well known in related arts, so the redundant description will be omitted here. The supporting plate 11 can be formed by covering an aging-resistant rubber onto a steel plate, for example, but the embodiment of the disclosure is not limited thereto.

A location of the sensing element 13 can be designed flexibly, based on a type of the sensing element. For example, the sensing element 13 is provided on at least one supporting plate 11 of each of the bearing layers 1. Also, for example, the sensing element 13 is provided on at least one side wall 12′ of each of the bearing layers 1.

In different examples, the sensing element 13 can be a pressure sensor 13 or a photoelectric sensor 132. The location of the sensing element can be designed differently for the pressure sensor 13 and the photoelectric sensor, which will be described below by way of example.

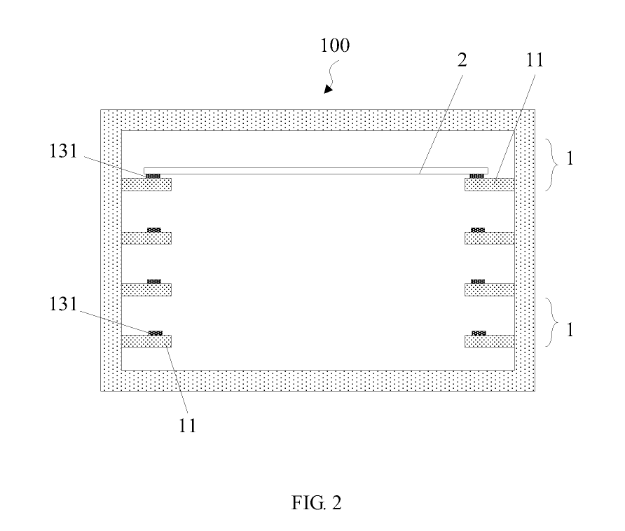

As illustrated in FIG. 2, when the sensing element 13 is implemented as a pressure sensor 131, the pressure sensor 131 can be provided on a top surface of the supporting plate 11 so that the substrate 2 presses against the pressure sensor 131 when it is placed on the supporting plate 11. In this embodiment, a configuration that the pressure sensor 131 is provided on the surface of the supporting plate 11 is adopted, which is easy to achieve and maintain.

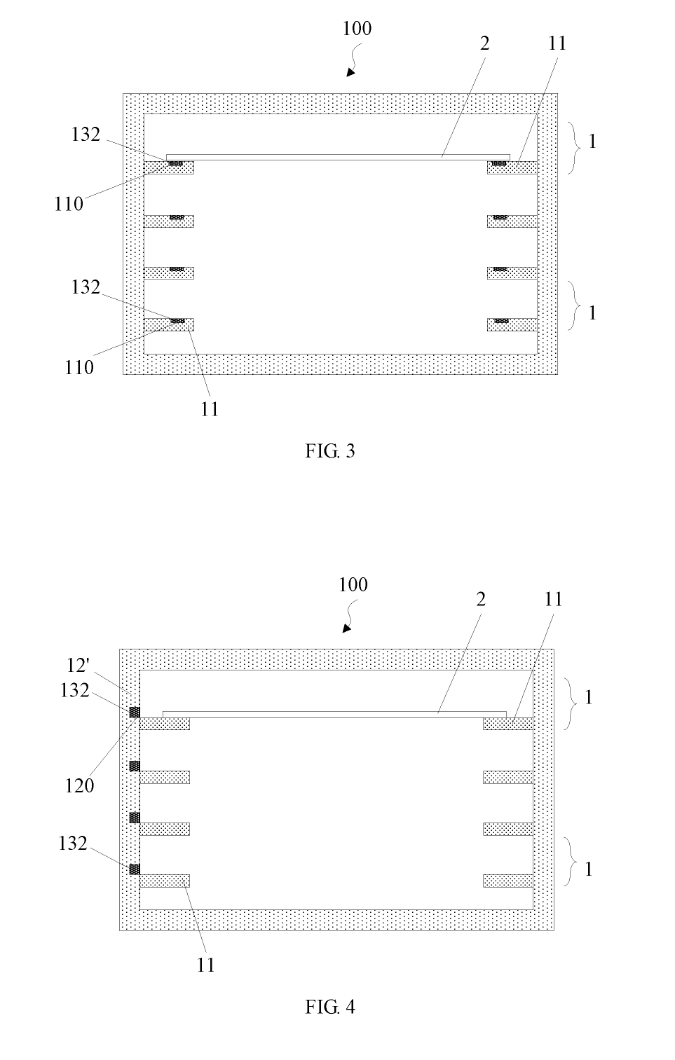

As illustrated in FIG. 3, when the sensing element 13 is implemented as a photoelectric sensor 132, the photoelectric sensor 132 can be provided into a groove 110 formed in the top surface of the supporting plate 11. Alternatively, as illustrated in FIG. 4, when the sensing element 13 is implemented as a photoelectric sensor 132, the photoelectric sensor 132 also can be provided into a groove 120 formed in at least one side wall 12′. In one example, if a thickness of the supporting plate 11 is T and a depth of the groove 11 is D, then D≦⅘ T.

As illustrated in FIGS. 3 and 4, when the substrate 2 is placed on the supporting plate 11, it can be sensed by the photoelectric sensor 132 in the groove 110 formed in the top surface of the supporting plate 11 or the photoelectric sensor 132 in the groove 120 formed in the side wall 12′. Furthermore, since the photoelectric sensor 132 is provided in the above-mentioned groove 110 or 120, it will not obstruct any operations performed to the substrate. In this embodiment, a scattered reflection photoelectric sensor can be adopted as the photoelectric sensor 132.

In one example, the warning element 14 is an indicator light or an infrared light-emitting device. When the substrate cassette 100 is operated by the mechanical arm, the light emitted from the indicator light can be indentified by a corresponding identification apparatus provided on the mechanical arm, to inform the mechanical arm that the substrate 2 has been placed on the bearing layer 1 corresponding to the indicator light. Of course, the indicator light can be observed by the operator directly. Similarly, the light emitted from the infrared light emitting device can be indentified by a corresponding identification apparatus provided on the mechanical arm, to inform the mechanical arm that the substrate 2 has been placed on the bearing layer 1 corresponding to infrared light emitting device. In one example, the above-mentioned identification apparatus can be an infrared receiver. Internal circuits of the infrared receiver include an infrared monitoring diode, an amplifier, a limiter, a band-pass filter, an integral circuit, a comparator etc., the configurations and operating principles of which are well known techniques in related arts, so the redundant description will be omitted here.

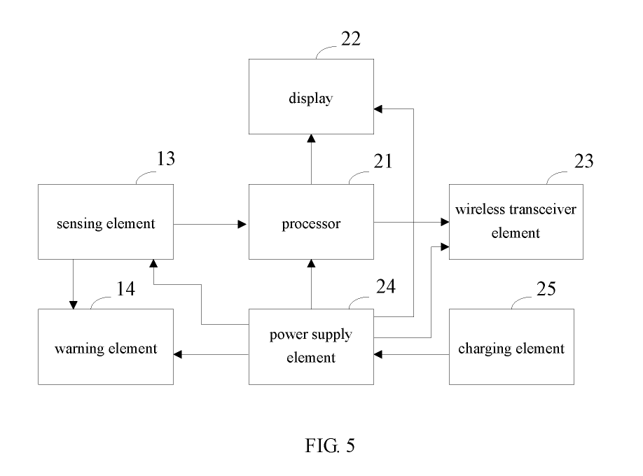

In one example, as illustrated in FIG. 5, the substrate cassette 100 can further includes a processor 21 and a display 22 to process and display signals from the sensing element 13 (for example, the pressure sensor 131 and the photoelectric sensor 132) when the substrate 2 is sensed by the sensing element 13. The processor 121 is electrically connected with respective sensing elements 13, and is configured to process sensing signals from respective sensing elements. The processor 21 is further connected with the display 22, and the display 22 is configured to display processing results from the processor 21.

In one example, the signals processed by the processor 21 can be sent to a target receiver by a wireless network. For example, the substrate cassette 100 can further include a plurality of wireless transceiver elements 23 which are connected with the processors 12 respectively. The transceiver 23 is configured to emit warning information to the target transceiver according to processing results from the processor 21. For example, the processing results from the processor 21 are sent to a handheld electronic device or a computer of the operator by the wireless transceiver element 23, to facilitate record, view or check.

In one example, the substrate cassette 100 further includes a power supply element which is configured to supply power to the processor 12, the display 22, respective sensing elements 13, respective wireless transceiver elements 23 and respective warning elements 14. The power supply element can be a lithium battery pack, for example, but the embodiment of the disclosure is not limited thereto.

In one example, the substrate cassette 100 further includes a charging element 25 which charges the power supply element 24. The charging element can be a power transformer, for example, but the embodiment of the disclosure is not limited thereto.

It should be noted that, the processor 21, the wireless transceiver 23, the power supply element 24 and the charging element 25 can be provided in the housing of the substrate cassette 100, in the embodiments of the disclosure. Generally, the substrate cassette 100 is at least provided with an opening through which the substrate 2 is placed into the substrate cassette 100 or the substrate 2 is picked up from the substrate cassette 100, which will be omitted here. In addition, the display 22 can be provided on any surface of the substrate cassette 100 which has no opening, to facilitate observation.

The substrate cassette provided by the embodiment of the disclosure can detect, by the sensing element provided in the bearing layer 1, whether the bearing layer bears the substrate; and can send, by the warning element, a warning signal when the bearing layer 1 bears the substrate; so that the operator or the conveying apparatus can take corresponding actions according to the warning signal sent from the warning element to avoid the problem that the substrates having been placed inside the substrate cassette are crashed or broken etc., when the substrate cassette is unsuitably operated.

It is obviously for those skilled in this art that any change or variation can be made to the embodiments without a departure from the spirit and scope of the invention. As such, these changes or variations are intended to be included within the invention, insofar as they are within the scope of the appended claims or the equivalents thereof.

This application claims the benefit of priority from Chinese patent application No. 201520704730.X, titled “a substrate cassette” and filed on Sep. 10, 2015, the disclosure of which is incorporated herein in its entirety by reference as a part of the present application.

1. A substrate cassette, defining multiple bearing layers therein, each of the bearing layer being configured to bearing a substrate thereon, a sensing element being provided in each of the bearing layers and a warning element being provided outside the substrate cassette to correspond to the sensing element, wherein,
the sensing element is configured to sense a substrate on the bearing layer; and
the warning element is configured to send a warning signal upon the substrate being sensed by the sensing element.

2. The substrate cassette according to claim 1, wherein each of the bearing layers comprises at least one side wall and at least one supporting plate fixed on the side wall.

3. The substrate cassette according to claim 2, wherein the side wall of the bearing layer is defined by at least one inner wall of the substrate cassette.

4. The substrate cassette according to claim 2, wherein the sensing element is provided in at least one supporting plate of each of the bearing layers, and the sensing element is a pressure sensor or a photoelectric sensor.

5. The substrate cassette according to claim 2, wherein the sensing element is provided on the at least one side wall of each of the bearing layers, and the sensing element is a photoelectric sensor.

6. The substrate cassette according to claim 4, wherein the photoelectric sensor is a scattered reflection photoelectric sensor.

7. The substrate cassette according to claim 4, wherein a groove is provided in a top surface of the supporting plate, and the sensing element is provided in the groove.

8. The substrate cassette according to claim 5, wherein a groove is provided in the at least one side wall of each of the bearing layers, and the sensing element is provided in the groove.

9. The substrate cassette according to claim 1, wherein the warning element is an indicator light or an infrared light-emitting device.

10. The substrate cassette according to claim 9, further comprising:
a processor, electrically connected with respective sensing elements and configured to process sensing signals from the respective sensing elements; and
a display, connected with the processor and configured to display processing results from the processor.

11. The substrate cassette according to claim 10, further comprising a wireless transceiver element which is electrically connected with the processor and configured to send warning information to a target receiver according to the processing results from the processor.

12. The substrate cassette according to claim 11, further comprising a power supply element which is connected with at least one of the processor, the display, the respective sensing elements, the respective wireless transceivers and the respective warning elements, to supply power thereto.

13. The substrate cassette according to claim 12, further comprising a charging element which is connected with the power supply element to charge the power supply element.

14. The substrate cassette according to claim 3, wherein the sensing element is provided in at least one supporting plate of each of the bearing layers, and the sensing element is a pressure sensor or a photoelectric sensor.

15. The substrate cassette according to claim 3, wherein the sensing element is provided on the at least one side wall of each of the bearing layers, and the sensing element is a photoelectric sensor.

16. The substrate cassette according to claim 4, wherein the sensing element is provided on the at least one side wall of each of the bearing layers, and the sensing element is a photoelectric sensor.

17. The substrate cassette according to claim 14, wherein the sensing element is provided on the at least one side wall of each of the bearing layers, and the sensing element is a photoelectric sensor.

18. The substrate cassette according to claim 5, wherein the photoelectric sensor is a scattered reflection photoelectric sensor.

19. The substrate cassette according to claim 14, wherein the photoelectric sensor is a scattered reflection photoelectric sensor.

20. The substrate cassette according to claim 15, wherein the photoelectric sensor is a scattered reflection photoelectric sensor.
